(19) United States
(12) Patent Application Publication
(10) Pub. No.: US 2009/0137115 A1
(43) Pub. Date: May 28, 2009

(54) METHOD OF MANUFACTURING METAL INTERCONNECTION

(76) Inventor: Seoug-Hun Jeong, Nowon-gu (KR)

Correspondence Address: SHERR & VAUGHN, PLLC, 620 HERNDON PARKWAY, SUITE 200, HERNDON, VA, 20170, US

(21) Appl. No.: 12/263,530

(22) Filed: Nov. 3, 2008

(30) Foreign Application Priority Data
Nov. 27, 2007 (KR) 10-2007-0121254

(51) Int. Cl. H01L 21/768

(52) U.S. Cl. 438/643; 257/E21.584

(57) ABSTRACT

A method of manufacturing a metal interconnection that includes forming a via hole and a trench in an insulating layer, and then filling the via hole and the trench with a first metal layer using a first base metal having an oxidation potential higher than a standard hydrogen potential, and then simultaneously removing the first metal layer while filling the via and the trench with a second metal layer composed of a second base metal having an oxidation potential lower than the standard hydrogen potential and an ionization tendency lower than an ionization tendency of the first base metal.

The present application claims priority under 35 U.S.C. §119 to Korean Patent Application No. 10-2007-0121254 (filed on Nov. 27, 2007), which is hereby incorporated by reference in its entirety.

### BACKGROUND

Recently, as semiconductor devices have become more highly integrated and process technology has been improved, an interconnection using copper instead of aluminum has been proposed to maximize characteristics of semiconductor devices, such as operation speed, resistance, and inter-metal parasitic capacity. However, the copper interconnection process has the following problems. First, since a volatile fluorine or chlorine compound is not formed in the copper interconnection process, plasma etching is impossible and etching characteristics are inferior. Thus, an interconnection process is complicated. Next, it is difficult to form a protective oxide layer having high surface density. Then, since copper is well diffused into a silicon layer, performance of a semiconductor device may be degraded and junction leakage current may be increased. Lastly, adhesive properties with the silicon layer is very low.

In order to overcome the problems of the copper interconnection process, there has been proposed a method of forming a contact of a semiconductor device using tungsten. However, an interconnection using tungsten and copper is disadvantageous in that the process becomes difficult due to a complicated layer structure and a difficult etching process, the loss of electrons at an interfacial layer, rough surface formation of the interconnection during the deposition process, moment of resistance is high, limitation exists in gap filling ability, and generation of bottlenecks due to concentration of electrons.

### SUMMARY

Embodiments relate to a method of manufacturing a metal interconnection which can form an interconnection using single metal such as copper without using an additional apparatus such as a plating apparatus.

Embodiments relate to a method of manufacturing a metal interconnection that may include at least one of the following: forming a first metal layer on and/or over a layer on and/or over which a metal interconnection is to be formed by using a first metal having an oxidation potential higher than a standard hydrogen potential, and then inducing a substitution reaction of the first metal and a second metal by exposing the first metal layer to an electrolyte solution including the second metal having an oxidation potential lower than the standard hydrogen potential and having ionization tendency lower than ionization tendency of the first metal.

Embodiments relate to a method that may include at least one of the following: forming a first metal layer over a substrate using a first base metal having an oxidation potential higher than a standard hydrogen potential; and then forming a second metal layer over the substrate by inducing a substitution reaction of the first base metal with a second base metal by exposing the first metal layer to an electrolyte solution including the second base metal. In accordance with embodiments, the second base metal has an oxidation potential lower than the standard hydrogen potential and also has an ionization tendency lower than an ionization tendency of the first base metal.

Embodiments relate to a method that may include at least one of the following: forming a device isolation layer in a substrate; and then forming a transistor over the substrate; and then forming an insulating layer over the substrate including the transistor; and then forming a via hole and a trench in the insulating layer; and then forming a diffusion barrier layer on walls of the via hole and the trench; and then filling the via hole and the trench with a first metal layer using a first base metal having an oxidation potential higher than a standard hydrogen potential; and then simultaneously removing the first metal layer while filling the via and the trench with a second metal layer composed of a second base metal having an oxidation potential lower than the standard hydrogen potential and an ionization tendency lower than an ionization tendency of the first base metal.

Embodiments relate to a method that may include at least one of the following: forming a transistor over a semiconductor substrate; and then forming an insulating layer over the semiconductor substrate including the transistor; and then forming a via hole and a trench extending through the insulating layer and exposing a portion of the semiconductor substrate; and then forming a first metal layer as a diffusion barrier layer over walls of the via hole and the trench; and then filling the via hole and the trench with a second metal layer composed of a second base metal; and then simultaneously forming a contact plug in the via hole and a metal interconnection in the trench by simultaneously removing the second metal layer and forming a third metal layer composed of a third base metal in the via hole and the trench.

### DRAWINGS

Example FIGS. 1 to 3 illustrate a method of manufacturing a metal interconnection in accordance with embodiments.

### DESCRIPTION

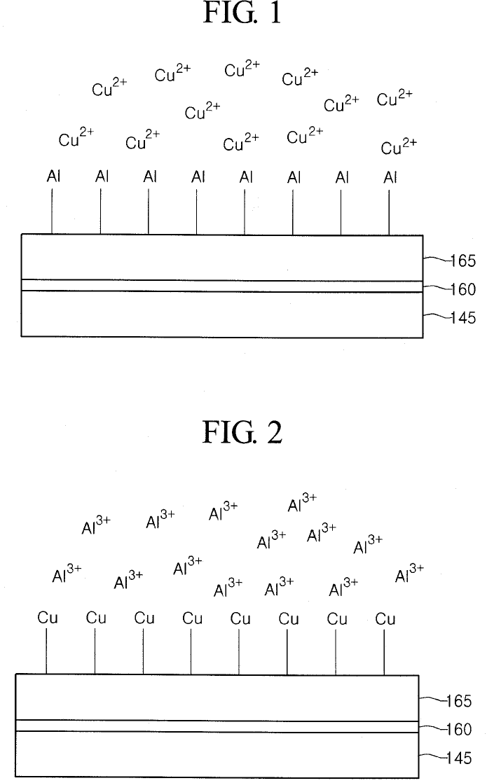

Example FIG. 1 is a sectional view illustrating a state in which a first metal layer is formed on and/or over a layer (e.g. an insulating layer) on and/or over which a metal interconnection is to be formed, and an electrolyte solution including second metal is coated. Example FIG. 2 is a sectional view illustrating a state in which a second metal layer is formed after a substitution reaction is performed according to ionization tendency.

Referring to example FIG. 1, a diffusion barrier 160 is formed on and/or over an insulating layer 145 on and/or over which a metal interconnection is to be formed. A first metal layer 165 is then formed on and/or over the diffusion barrier 160. The diffusion barrier 160 may include a metal such as Ta, TaN and the like to prevent ions of a second metal layer 161 to be subsequently formed from being diffused.

In accordance with embodiments, the first metal layer 165 includes a first base metal having an oxidation potential higher than a standard hydrogen potential, and the second metal layer 161 includes a second base metal having an oxidation potential lower than the standard hydrogen potential. The first base metal has ionization tendency greater than that of the second base metal. In accordance with embodiments, the first base metal may include at least one selected from the group consisting of Mg, Al, Zn, Fe and Li. The second base metal may include at least one selected from the group consisting of Cu, Au, Ag and Pt. For example, the first base metal may include aluminum and the second base metal may include copper. The first metal layer 165 may be laminated through a CVD (chemical vapor deposition) process, an ALD (atomic layer deposition) process and the like. If the second base metal is composed of copper, since copper has a low oxidation potential, it does not melt easily when exposed to acid. However, a copper electrolyte solution (an electrolyte solution included in the first base metal) is easily oxidized by reacting with metal (the first base metal) having high oxidation potential.

As illustrated in example FIG. 1, if the first metal layer 165 including aluminum is immersed in the copper electrolyte solution such as CUSO₄, a substitution reaction occurs due to the difference between ionization tendencies of the first and second base metals. The substitution reaction is a form of electrolysis plating and occurs without an electric current. Thus, the first base metal is ionized in the electrolyte solution and the second base metal is deposited on and/or over the diffusion barrier 160 to form the second metal layer 161. If the second metal layer 161 is formed, the electrolyte solution in which the first base metal is ionized is removed. Then, the second metal layer 161 forms a metal interconnection.

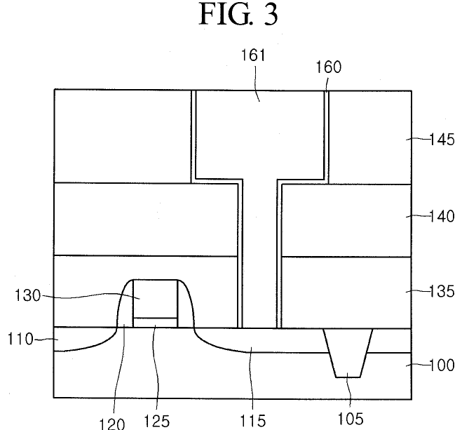

Example FIG. 3 is a side sectional view illustrating a state in which the metal interconnection is formed in a semiconductor device through the metal interconnection process according to the embodiment. Referring to example FIG. 3, the semiconductor device includes substrate 100, isolation layer 105, source area 110, drain area 115, gate insulating layer 125, spacer 120, gate electrode 130, first insulating layer 135, second insulating layer 140, third insulating layer 145, diffusion barrier 160 and metal interconnection 161. First insulating layer 135, second insulating layer 140, third insulating layer 145, diffusion barrier 160 and metal interconnection 161 are formed on and/or over substrate 100 including gate electrode 130. Since the structure and operation of the semiconductor device is well known to skilled in the art, detailed description thereof will be omitted.

In accordance with embodiments, first insulating layer 135, second insulating layer 140 and third insulating layer 145 can be formed in a multilayer structure in a multilayer interconnection structure according to positions, material and insulation properties of metal interconnection 161 and contact plug 162. Before metal interconnection 161 and contact plug 162 are formed as shown in example FIGS. 1 and 2, a via hole and corresponding trench are formed in first insulating layer 135, second insulating layer 140 and third insulating layer 145. Diffusion barrier 160 formed on and/or over the inner walls of the via hole and the trench may correspond to the diffusion barrier 160 as shown in example FIGS. 1 and 2. Then, a first base metal such as aluminum is filled in the via hole and the trench. The semiconductor device is then placed into a container having an electrolyte solution including a second base metal such as copper. Thus, an ion reaction occurs and the first base metal filled in the via hole and the trench is replaced with the second base metal so that contact plug 162 and metal interconnection 161 including the second base metal can be simultaneously formed.

Since embodiments uses a substitution reaction scheme based on the difference between ionization tendencies of metals, additional equipment such as deposition equipment or plating equipment is not necessary. Further, an interconnection can be formed using a single base metal such as copper, and an interconnection process can be simplified because a process of immersing a metal layer in the electrolyte solution is performed without using electricity. The interconnection can be formed using the single base metal such as copper, so that electron loss at an interface between layers, partial electron concentration and disconnection due to electron diffraction can be prevented, and an operation speed of a semiconductor device can be maximized through low interconnection resistance. The gap filling ability of a via hole having a large aspect ratio can also be maximized.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a first metal layer over a substrate using a first base metal having an oxidation potential higher than a standard hydrogen potential; and then
forming a second metal layer over the substrate by inducing a substitution reaction of the first base metal with a second base metal by exposing the first metal layer to an electrolyte solution including the second base metal, wherein the second base metal has an oxidation potential lower than the standard hydrogen potential and also has an ionization tendency lower than an ionization tendency of the first base metal.

2. The method of claim 1, wherein forming the first metal layer comprises:
forming a diffusion barrier over the substrate; and then
forming the first metal layer over the diffusion barrier.

3. The method of claim 2, wherein the diffusion barrier includes at least one selected from the group consisting of Ta and TaN.

4. The method of claim 1, wherein the first base metal includes at least one selected from the group consisting of Mg, Al, Zn, Fe and Li.

5. The method of claim 1, wherein the second base metal includes at least one selected from the group consisting of Cu, Au, Ag and Pt.

6. The method of claim 1, wherein the first metal layer is laminated through at least one of a chemical vapor deposition process and an atomic layer deposition process.

7. The method of claim 1, wherein the first base metal comprises aluminum and the electrolyte solution comprises a copper electrolyte solution.

8. The method of claim 1, wherein the electrolyte solution comprises a copper electrolyte solution containing CuSO₄.

9. The method of claim 1, wherein forming the second metal layer comprises substituting the second metal layer for the first metal layer through the substitution reaction and removing the electrolyte solution in which the first base metal is ionized.

10. A method comprising:
forming a device isolation layer in a substrate; and then
forming a transistor over the substrate; and then
forming an insulating layer over the substrate including the transistor; and then
forming a via hole and a trench in the insulating layer; and then
forming a diffusion barrier layer on walls of the via hole and the trench; and then
filling the via hole and the trench with a first metal layer using a first base metal having an oxidation potential higher than a standard hydrogen potential; and then
simultaneously removing the first metal layer while filling the via and the trench with a second metal layer composed of a second base metal having an oxidation potential lower than the standard hydrogen potential and an ionization tendency lower than an ionization tendency of the first base metal.

11. The method of claim 10, wherein the insulating layer has a multi-layer structure.

12. The method of claim 11, wherein the multi-layer structure comprises a first insulating layer, a second insulating layer and a third insulating layer.

13. The method of claim 10, wherein simultaneously removing the first metal layer while filling the via and the trench with a second metal layer comprises:
inducing a substitution reaction of the first base metal with the second base metal by exposing the first metal layer to an electrolyte solution that includes the second base metal.

14. The method of claim 10, wherein the diffusion barrier layer includes at least one selected from the group consisting of Ta and TaN.

15. The method of claim 10, wherein the first base metal includes at least one selected from the group consisting of Mg, Al, Zn, Fe and Li and the second base metal includes at least one selected from the group consisting of Cu, Au, Ag and Pt.

16. The method of claim 10, wherein the first base metal comprises aluminum and the electrolyte solution comprises a copper electrolyte solution.

17. The method of claim 10, wherein the electrolyte solution comprises a copper electrolyte solution containing CuSO₄.

18. A method comprising:
forming a transistor over a semiconductor substrate; and then
forming an insulating layer over the semiconductor substrate including the transistor; and then
forming a via hole and a trench extending through the insulating layer and exposing a portion of the semiconductor substrate; and then
forming a first metal layer as a diffusion barrier layer over walls of the via hole and the trench; and then
filling the via hole and the trench with a second metal layer composed of a second base metal; and then
simultaneously forming a contact plug in the via hole and a metal interconnection in the trench by simultaneously removing the second metal layer and forming a third metal layer composed of a third base metal in the via hole and the trench.

19. The method of claim 18, wherein the second base metal has an oxidation potential higher than a standard hydrogen potential, the third base metal has an oxidation potential lower than the standard hydrogen potential and an ionization tendency lower than an ionization tendency of the second base metal.

20. The method of claim 18, wherein simultaneously forming the contact plug in the via hole and the metal interconnection in the trench comprises:
inducing a substitution reaction of the second base metal with the third base metal by exposing the second metal layer to an electrolyte solution that includes the third base metal.
